(19) United States
(12) Patent Application Publication
(10) Pub. No.: US 2012/0074456 A1
(43) Pub. Date: Mar. 29, 2012

(54) LIGHT EMITTING DEVICE PACKAGE

(76) Inventor: Hongboem JIN, Seoul (KR)

(21) Appl. No.: 13/304,510

(22) Filed: Nov. 25, 2011

(30) Foreign Application Priority Data
Nov. 25, 2010 (KR) 10-2010-0118125

(51) Int. Cl. H01L 33/62; H01L 33/64

(52) U.S. Cl. 257/99; 257/E33.066; 257/E33.075

(57) ABSTRACT

A light emitting device package is disclosed. The disclosed light emitting device package includes a body comprising a cavity, and a recess formed at a bottom surface of the body, first and second lead frames mounted in the body, and a light source electrically connected with the first and second lead frames, wherein at least one of the first and second lead frames has a heat sink which is extended from a portion of the first or the second lead frames, and is disposed in the recess. The body includes a first coupler formed on at least a portion of the body. The heat sink includes a second coupler, to which the first coupler is coupled.

### CROSS-REFERENCE TO RELATED APPLICATION

This application claims the priority benefit of Korean Patent Application No. 10-2010-0118125, filed on Nov. 25, 2010 in the Korean Intellectual Property Office, the disclosure of which is incorporated herein by reference.

### BACKGROUND

1. Field

Embodiments relate to a light emitting device package.

2. Description of the Related Art

A light emitting diode (LED) is a device, which converts an electrical signal into light, using the characteristics of a compound semiconductor. Such an LED is applied to home electronic appliances, remote controllers, advertising display panels, indicators, various automation appliances, etc. The application range of LEDs is being gradually widened.

Meanwhile, when electricity is applied to a light emitting device package, a considerable amount of heat is generated from the light emitting device package. This heat not only degrades the durability and reliability of the light emitting device package, but also limits the functions and lifespan of the light emitting device package.

### SUMMARY

Embodiments provide a light emitting device package including a lead frame having a lateral extension to increase an exposed portion of the lead frame, and thus to enhance the heat sink function and heat dissipation function of the lead frame, thereby being capable of exhibiting more excellent heat dissipation effects and achieving an enhancement in reliability.

In one embodiment, a light emitting device package includes a body comprising a cavity, and a recess formed at a bottom surface of the body, first and second lead frames mounted in the body, and a light source electrically connected with the first and second lead frames, wherein at least one of the first and second lead frames has a heat sink which is extended from a portion of the first or the second lead frames, and is disposed in the recess, wherein the body further comprises a first coupler formed on at least a portion of the body, and wherein the heat sink comprises a second coupler, to which the first coupler is coupled.

The heat sink may be contacted at least a portion of one slide surface of the body.

The heat sink may have at least a portion contacting the recess.

The heat sink may have at least one bent portion.

The bent portion may be disposed at a corner region of the body.

The bent portion may have a rounded portion.

The heat sink may be extended from the first lead frame. The light source may be mounted on the first lead frame.

The first lead frame may form an anode terminal.

The recess may have a width greater than a width of the heat sink.

The recess may have a depth greater than a thickness of the heat sink.

The first coupler may be a groove, and the second coupler may be a protrusion to be coupled with the groove.

The first coupler may be a protrusion, and the second coupler may be a groove to be coupled with the protrusion.

The heat sink may has a hole through at least a portion of the heat sink.

At least a portion of the body may be protruded through the hole.

The heat sink may has at least a portion in which roughness are formed.

The heat sink may be made of an identical material to the first and second lead frames.

The light emitting device package may further include a bonding layer disposed between at least one side surface of the body and the heat sink.

The heat sink may include a coating layer formed on at least a portion of a surface of the heat sink.

### BRIEF DESCRIPTION OF THE DRAWINGS

Details of embodiments will be more clearly understood from the following detailed description taken in conjunction with the accompanying drawings, in which:

FIG. 1 is a perspective view illustrating a light emitting device package according to an exemplary embodiment of the present invention;

FIG. 2 is a cross-sectional view illustrating the light emitting device package shown in FIG. 1;.

FIG. 3 is a cross-sectional view illustrating the light emitting device package shown in FIG. 1;

FIG. 4 is a cross-sectional view illustrating a light emitting device package according to another embodiment;

FIG. 5 is a cross-sectional view illustrating a light emitting device package according to another embodiment;

FIG. 6 is a perspective view illustrating a light emitting device package according to another embodiment;

FIG. 7A is a perspective view illustrating a lighting apparatus including a light emitting device package according to an exemplary embodiment;

FIG. 7B is a cross-sectional view illustrating the lighting apparatus shown in FIG. 7A;

FIG. 8 is an exploded perspective view illustrating a liquid crystal display apparatus including a light emitting device according to an exemplary embodiment; and

FIG. 9 is an exploded perspective view illustrating a liquid crystal display apparatus including a light emitting device according to another embodiment.

### DETAILED DESCRIPTION OF EMBODIMENTS

Reference will now be made in detail to embodiments, examples of which are illustrated in the accompanying drawings. In the drawings, the thickness or size of each layer is exaggerated, omitted, or schematically illustrated for convenience of description and clarity. Also, the size or area of each constituent element does not entirely reflect the actual size thereof. Wherever possible, the same reference numbers will be used throughout the drawings to refer to the same or like parts.

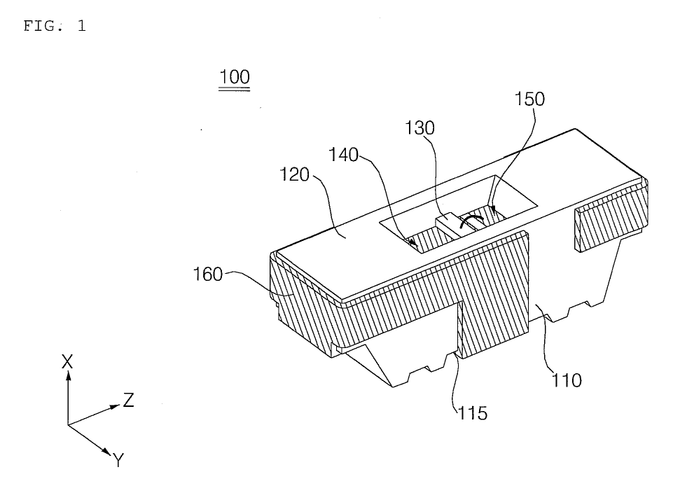

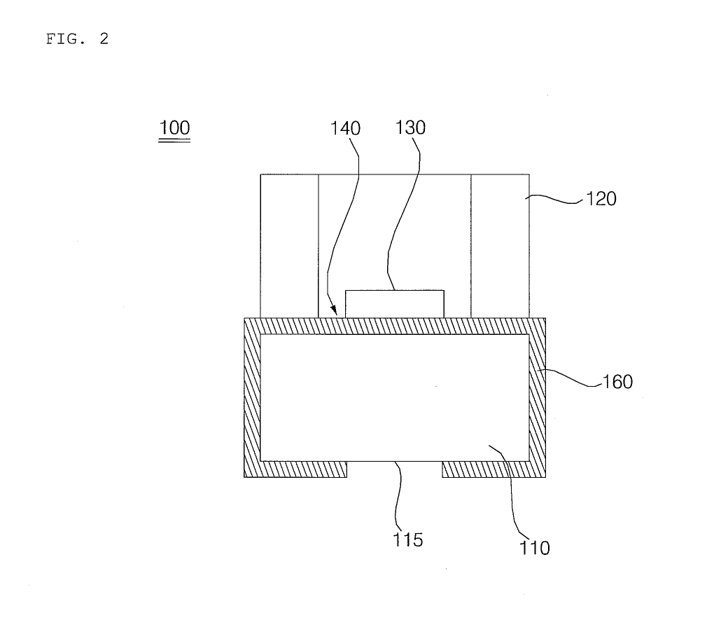

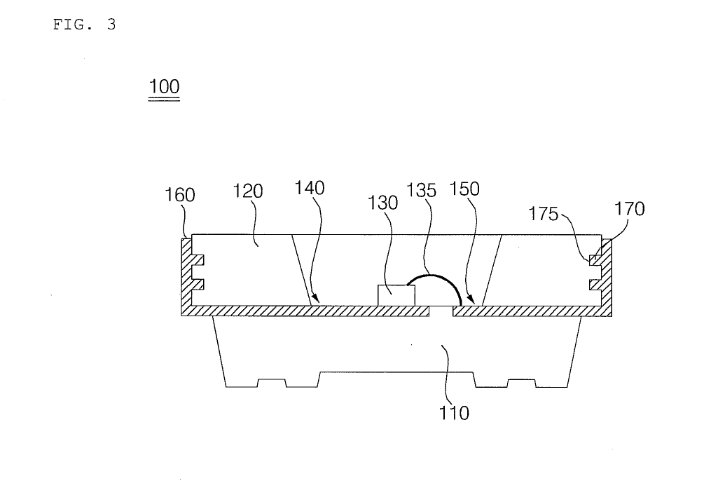

FIG. 1 is a perspective view illustrating a light emitting device package according to an exemplary embodiment of the present invention. FIG. 2 is a cross-sectional view illustrating the light emitting device package shown in FIG. 1. FIG. 3 is a cross-sectional view taken along a plane perpendicular to the plane of FIG. 2, illustrating the light emitting device package shown in FIG. 1.

In the following description, to explain the shape of the light emitting device package according to the illustrated embodiment in more detail, a longitudinal direction of the light emitting device package is referred to as a “longitudinal direction Z”, a horizontal direction perpendicular to the longitudinal direction Z is referred to as a “horizontal direction Y”, and a height direction perpendicular to both the longitudinal direction Z and the horizontal direction Y is referred to as a “height direction X”.

That is, FIG. 2 is a cross-sectional view taken along an X-Y plane of the light emitting device package shown in FIG. 1, and viewed in the longitudinal direction Z, and FIG. 3 is a cross-sectional view taken along a Z-X plane of the light emitting device package shown in FIG. 1, and viewed in the horizontal direction Y.

Referring to FIGS. 1 to 3, the light emitting device package according to the illustrated embodiment, which is designated by reference numeral “100”, includes a body 110 having a cavity while being provided, at a bottom surface thereof, with a recess 115, first and second lead frames 140 and 150 mounted in the cavity of the body 110, and a light source 130 mounted in the cavity of the body 110 while being electrically connected with the light source 130, wherein at least one of the first and second lead frames 140 and 150 has a heat sink 160 which is extended from a portion of the first or the second lead frames 140 and 150, and is disposed in the recess 115. The body 110 includes a second coupler 175 formed on at least a portion of the body 110. The heat sink 170 includes a first coupler 170, to which the second coupler 175 is coupled.

The body 110 may be made of at least one selected from among a resin such as Polyphthalamide (PPA), silicon (Si), aluminum (Al), aluminum nitride (AlN), a liquid crystal polymer such as photosensitive glass (PSG), polyamide 9T (PA9T), sindiotactic polystyrene (SPS), a metal, sapphire (Al203), and beryllium oxide (BeO), or may be a printed circuit board (PCB). The body 110 may be formed by an injection molding process, an etching process or the like, although the present disclosure is not limited thereto.

The body 110 may have an inclined surface at an inner surface thereof. In accordance with the inclination of the inclined surface, the reflection angle of light emitted from the light source 130 may be varied. Thus, the orientation angle of outwardly emitted light may be adjusted.

The smaller the orientation angle of light, the greater the convergence of light emitted from the light source 130 to the outside. Conversely, the greater the orientation angle of light, the smaller the convergence of light emitted from the light source 130 to the outside.

When viewing the cavity formed in the body 110 from the top side, the cavity 120 may have a circular, square, polygonal, elliptical shape or the like and may have rounded corners. Of course, the cavity is not limited to the above-described shapes.

The light source 130 is electrically connected to the first and second lead frames 140 and 150. For example, the light source 130 may be wire-bonded to the first and second lead frames 140 and 150 by a wire 135.

The light source 130 may be, for example, a colored light emitting diode to emit red, green, blue and white light, or an ultraviolet (UV) light emitting diode to emit ultraviolet light, although the present disclosure is not limited thereto. One or more light emitting diodes may be mounted.

The light emitting diode may be of a horizontal type wherein all electric terminals are disposed on an upper surface thereof, or of a vertical type wherein electric terminals are distributed on upper and lower surfaces thereof. Alternatively, the light emitting diode may be of a flip-chip type.

A resin encapsulator (not shown) may fill the cavity, to cover the light source 130.

The resin encapsulator (not shown) may be made of silicon, epoxy resin, or other resin materials. The resin encapsulator may be formed by filling the cavity with an encapsulating material, and curing the filled material using ultraviolet light or heat.

The resin encapsulator (not shown) may include a fluorescent substance. The kind of the fluorescent substance may be selected in accordance with the wavelength of light emitted from the light source 130 in order to realize emission of white light.

The fluorescent substance may be a blue, bluish green, green, yellowish green, yellow, yellowish red, orange, or red light-emitting fluorescent substance in accordance with the wavelength of light emitted from the light source 130, although the present disclosure is not limited thereto.

That is, the fluorescent substance may be excited by light emitted from the light source 130 at a first wavelength, to generate light of a second wavelength. For example, when the light source 130 is a blue light emitting diode, and the fluorescent substance is a yellow fluorescent substance, the yellow fluorescent substance is excited by blue light, thereby emitting yellow light. In this case, the light emitting device package 100 may provide white light as the blue light generated from the blue light emitting diode and the yellow light generated in accordance with excitation by the blue light are mixed.

Similarly, when the light source 130 is a green light emitting diode, a magenta fluorescent substance or a mixture of blue and red fluorescent substances may be used as the fluorescent substance. Also, when the light source 130 is a red light emitting diode, a cyan fluorescent substance or a mixture of blue and green fluorescent substances may be used as the fluorescent substance.

The fluorescent substance may be a known fluorescent substance such as a YAG-based, TAG-based, sulfide-based, silicate-based, aluminate-based, nitride-based, carbide-based, nitridosilicate-based, borate-based, fluoride-based, or phosphate-based fluorescent substance.

The first and second lead frames 140 and 150 may be made of at least one of titanium (Ti), copper (Cu), nickel (Ni), gold (Au), chromium (Cr), tantalum (Ta), platinum (Pt), tin (Sn), silver (Ag), phosphor (P), aluminum (Al), indium (In), palladium (Pd), cobalt (Co), silicon (Si), germanium (Ge), hafnium (Hf), ruthenium (Ru), and iron (Fe), or an alloy thereof. The first and second lead frames 140 and 150 may have a single-layer structure or a multilayer structure, although the present disclosure is not limited thereto.

The first and second lead frames 140 and 150 may be spaced apart from each other, to be electrically isolated from each other. The first lead frame 140 may directly contact the light source 130 or may be electrically connected to the light source 130 via a material having conductivity. One of the first and second lead frames 140 and 150 may function as an anode terminal, and the other of the first and second lead frames 140 and 150 may function as a cathode terminal. Also, the second lead frame 150 may be electrically connected to the light source 130 by the wire 135, although the present disclosure is not limited thereto. Accordingly, as a power source is connected to the first and second lead frames 140 and 150, electricity may be applied to the light source 130. Meanwhile, a plurality of lead frames (not shown) may be mounted in the body 110; and each of the lead frames (not shown) may be electrically connected to associated ones of a plurality of light sources, although the present disclosure is not limited thereto.

The first lead frame 140 has a heat sink 160 extended externally from the body 110 in the longitudinal direction Z of the body 110. Practically, at least one of the first and second lead frames 140 and 150 may have a longitudinal extension to form the heat sink 160. The extension may be bent to connect side surfaces of the body 110. Alternatively, a separate member (not shown) may be coupled to the first and second lead frames 140 and 150 such that it connects at least one side surface of the body 110. Alternatively, a material such as a resin material having thermal conductivity may be coated over the side surfaces of the body 110. Of course, the present disclosure is not limited to the above-described structures.

Meanwhile, the heat sink 160 may be made of the same material as the first and second lead frames 140 and 150, although the present disclosure is not limited thereto. That is, the heat sink may be made of at least one of titanium (Ti), copper (Cu), nickel (Ni), gold (Au), chromium (Cr), tantalum (Ta), platinum (Pt), tin (Sn), silver (Ag), phosphor (P), aluminum (Al), indium (In), palladium (Pd), cobalt (Co), silicon (Si), germanium (Ge), hafnium (Hf), ruthenium (Ru), and iron (Fe), or an alloy thereof, although the present disclosure is not limited thereto.

Although the heat sink 160 is illustrated as extending from the first lead frame 140, as shown in FIG. 3, it may be formed to extend from at least one of the first and second lead frames 140 and 150. A plurality of lead frames (not shown) may be formed, and a plurality of heat sinks 160 may extend from selected ones of the lead frames, although the present disclosure is not limited thereto.

Meanwhile, the heat sink 160 may be formed at the first lead frame 140, on which the light source 130 is mounted. In accordance with this structure, it may be possible to more effectively transfer heat generated in the light source 130 to the heat sink 160. Accordingly, the heat dissipation function of the light emitting device package 100 may be further enhanced.

The heat sink 160 may be formed at the anode terminal. Since heat dissipation of the light emitting device package 100 is mainly carried out at the anode terminal, it may be possible to more effectively achieve an increase in the heat dissipation effects of the light emitting device package 100.

The heat sink 160 may include a bent portion to bring the heat sink 160 into connect with the side surfaces of the body 110, respectively. A bent portion may have a rounded portion. The bent portion may be formed at corner regions of the body 110, respectively.

Since the heat sink 160 is formed to extend from the first and second lead frames 140 and 140 while extending along side surfaces of wall portions 120 of the body 110, it may be possible to further increase the exposed areas and volumes of the first and second lead frames 140 and 150, and thus to enhance the heat sink functions and heat dissipation functions of the first and second lead frames 140 and 150. Accordingly, it may be possible to achieve an enhancement in the reliability of the light emitting device package 100.

Meanwhile, the heat sink 160 may be bent to extend along the bottom surface of the body 110. As described above, the body 110 may be provided, at the bottom surface thereof, with the recess 115 to receive the extension portion of the heat sink 160. As the body 110 is provided with the recess 115, and the heat sink 160 is partially received in the recess 115, it may be possible to more stably form the heat sink 160.

The recess 115 may have a depth greater than the thickness of the heat sink 160, and a width greater than the width of the heat sink 160, in order to allow the heat sink 160 to be more easily received in the recess 115.

As the body 110 includes the recess 115, and the heat sink 160 is disposed in the recess 115, it may be possible to more reliably fix the heat sink 160 to the body 110.

Meanwhile, referring to FIG. 3, the heat sink 160 may include the first coupler 170, and the body 110 may include the second coupler 175.

The first coupler 170 may be formed at an inner surface of the heat sink 160 connecting the body 110. The first coupler 170 may include at least one protrusion. The second coupler 175 may be formed to be engagable with the first coupler 170. The second coupler 175 may include at least one groove. Meanwhile, the second coupler 175 may have a structure different from the illustrated structure, for example, a hole structure, so long as it may be coupled with the first coupler 170. Of course, the present disclosure is not limited to the above-described structures.

Although the first coupler 170, which includes protrusions, is formed at the heat sink 160, and the second coupler 175, which includes grooves, in order to correspond to the first coupler 170, is formed at the body 110, in the case of FIG. 3, the present disclosure is not limited thereto. For example, reversed structures may be employed. That is, protrusions (not shown) may be formed on at least a portion of the body 110, and grooves (not shown) corresponding to the protrusions (not shown) may be formed in at least a portion of the heat sink 160.

As the heat sink 160 is provided with the first coupler 170, and the body 110 is provided with the second coupler 175 corresponding to the first coupler 170, it may be possible to more reliably fix the heat sink 160 to the body 110.

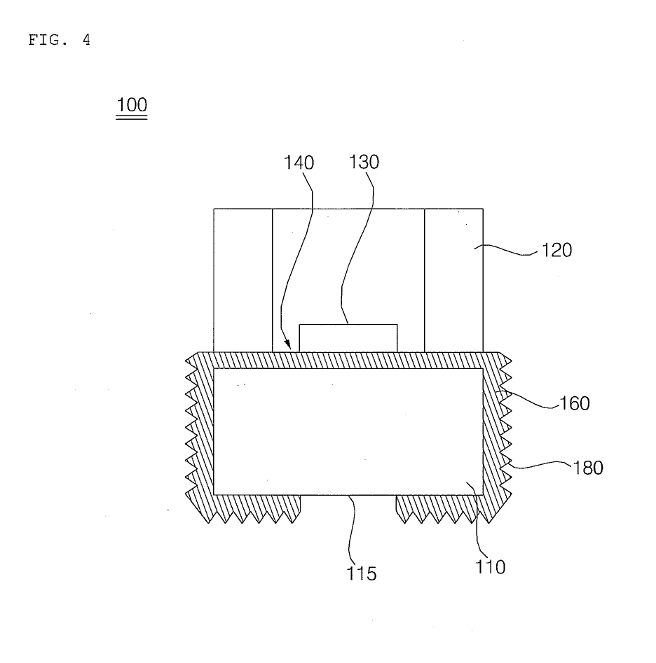

FIG. 4 is a cross-sectional view illustrating a light emitting device package according to another embodiment.

Referring to FIG. 4, the heat sink 160 may include roughness 180 formed on at least a portion of the heat sink 160.

For example, the roughness 180 may be formed on an outer surface of the heat sink 160, although the present disclosure is not limited thereto.

As the heat sink 160 includes the roughness (not shown), it may be possible to increase the surface area of the heat sink 160, and thus to achieve an enhancement in the heat dissipation effects of the heat sink 160.

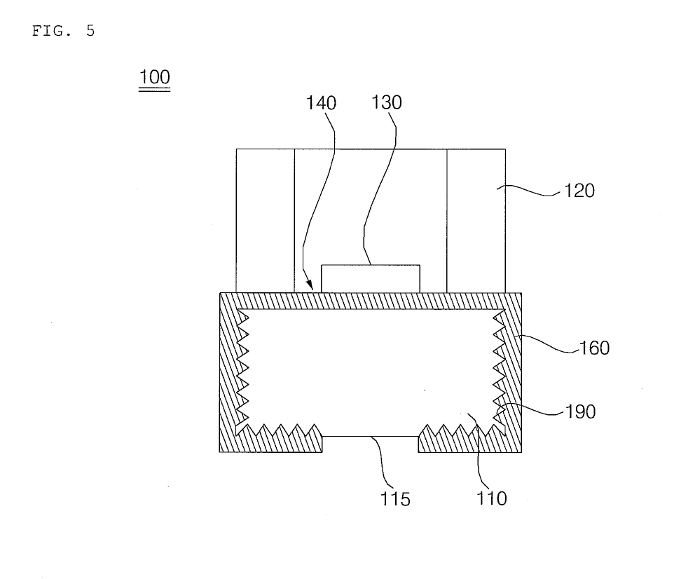

FIG. 5 is a cross-sectional view illustrating a light emitting device package according to another embodiment.

Referring to FIG. 5, a bonding layer 190 may be disposed between at least one surface of the body 110 and the heat sink 160.

As the bonding layer 190 is disposed between the body 110 and the heat sink 160, it may be possible to reliably fix the heat sink 160 to the body 110. The bonding layer 190 may be formed by coating a material of the bonding layer 190 over one side surface of the body 110, disposing the heat sink 160 to contact the coated bonding layer (not shown), and then curing the coated bonding layer (not shown), although the present disclosure is not limited thereto.

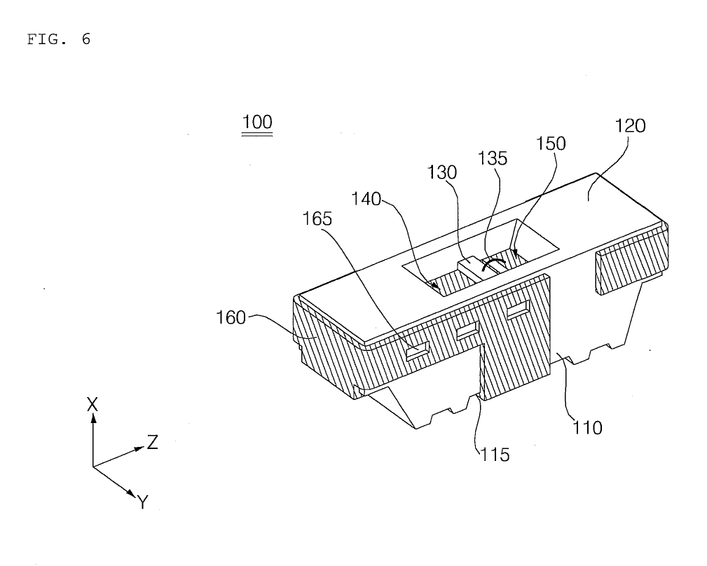

FIG. 6 is a perspective view illustrating a light emitting device package according to another embodiment.

Referring to FIG. 6, the heat sink 160 may have holes 165.

The holes 165 may be formed by etching or pressing the heat sink 160, or preparing the first and second lead frames 140 and 150 to have the holes 165, although the present disclosure is not limited thereto. Although a plurality of holes 165 having a rectangular shape is formed at the heat sink 160, which is connected to the first lead frame 140, in the case of FIG. 6, the holes 165 may be formed at the heat sink 160, which is connected to the second lead frame 150. Also, the holes 165 may have other shapes, for example, a circular shape or a polygonal shape, although the present disclosure is not limited thereto.

Meanwhile, a portion of the body 110 may be protruded into at least one of the holes 165, or at least one of the holes 165 may be filled with a portion of the body 110, although the present disclosure is not limited thereto.

As the holes 165 are formed at the heat sink 160, the exposed area of the heat sink 160 increases, thereby enhancing the heat sink function and heat dissipation effects of the heat sink 160. Thus, an enhancement in the reliability of the light emitting device package 100 may be achieved.

The light emitting device package according to any one of the above-described embodiments may be applied to a lighting system. The lighting system may be a lighting apparatus, a backlight unit, a liquid crystal display device, etc, although the present disclosure is not limited thereto.

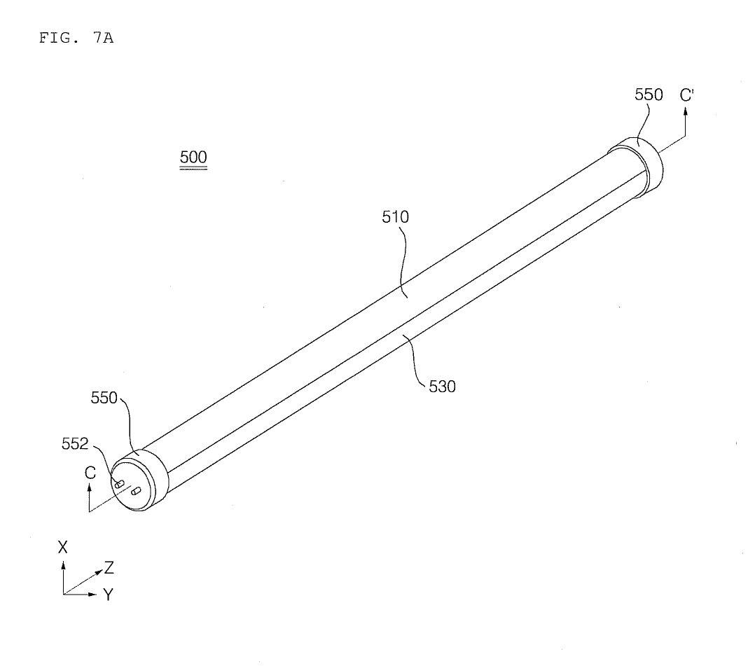

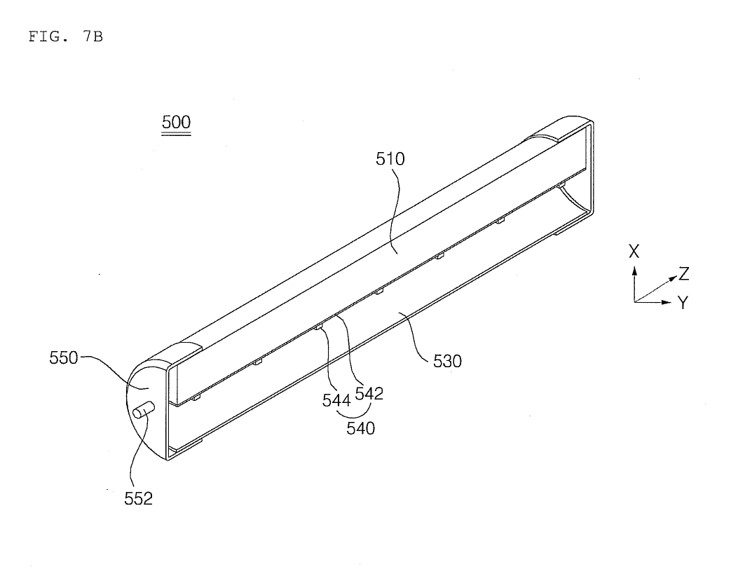

FIG. 7A is a perspective view illustrating a lighting apparatus including a light emitting device package according to an exemplary embodiment. FIG. 7B is a cross-sectional view taken along a plane extending in a longitudinal direction Z and a height direction X and viewed in a horizontal direction Y, illustrating the lighting apparatus of FIG. 7A.

Referring to FIGS. 7A and 7B, the lighting apparatus, which is designated by reference numeral “500” may include a body 510, a cover 530 coupled to the body 510, and end caps 550 located at both ends of the body 510.

A light emitting device module 540 is coupled to a lower surface of the body 510. The body 510 may be made of a metal material exhibiting excellent conductivity and excellent heat radiation effects to outwardly dissipate heat generated from light emitting device packages 544 through an upper surface of the body 510.

The light emitting device packages 544 may be mounted on a printed circuit board (PCB) 542 in multiple rows while having various colors, to form a multi-color array. The light emitting device packages 544 may be mounted at the same distance, or may be mounted at different distances to enable brightness adjustment, if necessary. The PCB 542 may be a metal core PCB (MCPCB) or a PCB made of a flame retardant-4 (FR4) material.

Each light emitting device package 544 may include a heat sink (not shown) so that it may have an enhanced heat dissipation function. Thus, it may be possible to enhance the reliability and efficiency of the light emitting device package 544. In addition, it may be possible to extend the life span of the lighting apparatus 500, which includes the light emitting device packages 544.

The cover 530 may have a circular shape to surround the lower surface of the body 510, although the present disclosure is not limited thereto.

The cover 530 protects the light emitting device module 540 from external foreign matter, etc. The cover 530 may contain light diffusion particles to achieve anti-glare effects and uniform emission of light generated from the light emitting device packages 544. At least one of the inner and outer surfaces of the cover 530 may be provided with a prism pattern. Also, a fluorescent substance layer may be coated over at least one of the inner and outer surfaces of the cover 530.

Since the light generated from the light emitting device packages 544 is outwardly emitted through the cover 530, the cover 530 should have high light transmittance and heat resistance sufficient to endure heat generated from the light emitting device packages 544. To this end, the cover 530 may be formed of polyethylene terephthalate (PET), polycarbonate (PC) or polymethylmethacrylate (PMMA).

The end caps 550 may be disposed at both ends of the body 510 and function to seal a power supply device (not shown). Each end cap 550 is provided with power pins 552, so that the lighting apparatus 500 in accordance with the illustrated embodiment may be directly connected to a terminal, which is provided for a conventional fluorescent lamp, without an additional connector.

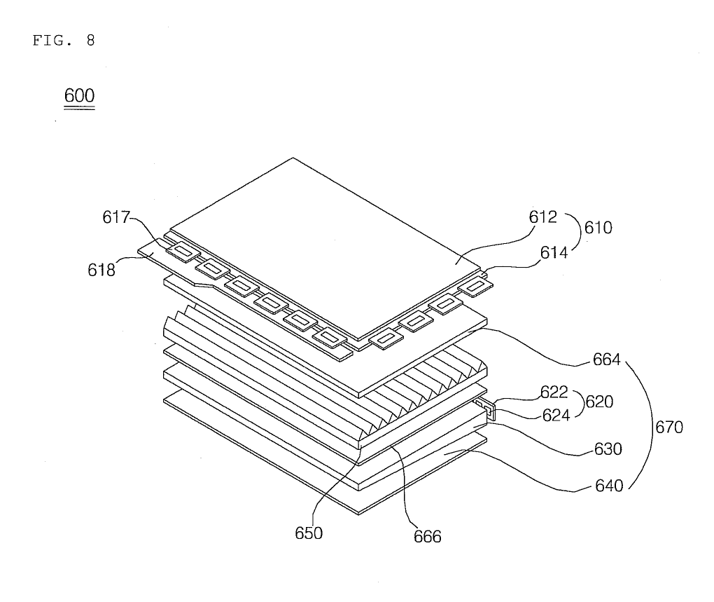

FIG. 8 is an exploded perspective view illustrating a liquid crystal display apparatus including a light emitting device according to an exemplary embodiment.

FIG. 8 illustrates an edge-light type liquid crystal display apparatus 600. The liquid crystal display apparatus 600 may include a liquid crystal display panel 610 and a backlight unit 670 to supply light to the liquid crystal display panel 610.

The liquid crystal display panel 610 may display an image using the light supplied from the backlight unit 670. The liquid crystal display panel 610 may include a color filter substrate 612 and a thin film transistor substrate 614, which are opposite each other with liquid crystals interposed therebetween.

The color filter substrate 612 may realize the color of an image displayed on the liquid crystal display panel 610.

The thin film transistor substrate 614 is electrically connected to a PCB 618, on which a plurality of circuit elements is mounted, by means of a drive film 617. The thin film transistor substrate 614 may apply drive voltage provided by the PCB 618 to liquid crystals in response to a drive signal transmitted from the PCB 618.

The thin film transistor substrate 614 may include thin film transistors and pixel electrodes in the form of thin films formed on another substrate made of a transparent material such as glass or plastic.

The backlight unit 670 includes a light emitting device module 620 to emit light, a light guide plate 630 to change light emitted from the light emitting device module 620 into planar light and to transmit the planar light to the liquid crystal display panel 610, a plurality of films 650, 666 and 664 to achieve uniformity in brightness distribution and improved vertical incidence of light emerging from the light guide plate 630, and a reflection sheet 640 to reflect light emitted rearwards from the light guide plate 630 toward the light guide plate 630.

The light emitting device module 620 may include a plurality of light emitting device packages 624 and a PCB 622 on which the plurality of light emitting device packages 624 is mounted to form an array.

In particular, each light emitting device package 624 may include a heat sink (not shown) so that it may have an enhanced heat dissipation function. Thus, it may be possible to enhance the reliability and efficiency of the light emitting device package 624. In addition, it may be possible to extend the life span of the lighting apparatus 600, which includes the light emitting device packages 624.

Meanwhile, the backlight unit 670 may include a diffusion film 666 to diffuse light incident thereupon from the light guide plate 630 toward the liquid crystal display panel 610, and a prism film 650 to condense the diffused light so as to enhance vertical light incidence. The backlight unit 670 may further include a protection film 664 to protect the prism film 650.

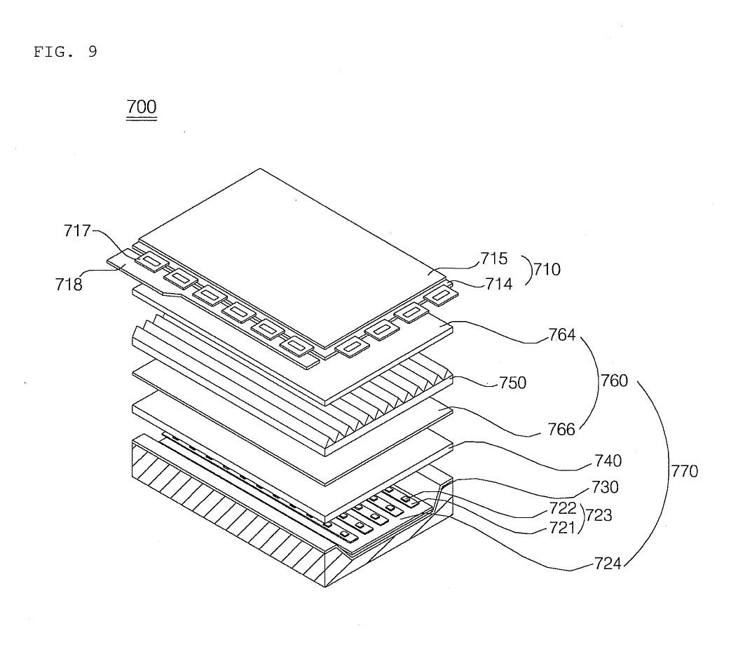

FIG. 9 is an exploded perspective view illustrating a liquid crystal display apparatus including a light emitting device according to another embodiment. The same configuration as that illustrated in FIG. 8 and described with reference to FIG. 8 will not be repeatedly described in detail.

FIG. 9 illustrates a direct type liquid crystal display apparatus 700 including a liquid crystal display panel 710 and a backlight unit 770 to supply light to the liquid crystal display panel 710.

The liquid crystal display panel 710 is identical to that of FIG. 8 and, as such, no detailed description thereof will be given.

The backlight unit 770 may include a plurality of light emitting device modules 723, a reflection sheet 724, a lower chassis 730 in which the light emitting device modules 723 and reflection sheet 724 are accommodated, and a diffusion sheet 740 and a plurality of optical films 760, which are disposed over the light emitting device modules 723.

Each light emitting device module 723 may include a plurality of light emitting device packages 722, and a PCB 721 on which the plurality of light emitting device packages 722 is mounted to form an array.

In particular, each light emitting device package 722 may include a heat sink (not shown) so that it may have an enhanced heat dissipation function. Thus, it may be possible to enhance the reliability and efficiency of the light emitting device package 722. In addition, it may be possible to extend the life span of the backlight unit 770, which includes the light emitting device packages 722.

The reflection sheet 724 reflects light generated by the light emitting device packages 722 toward the liquid crystal display panel 710, to achieve an enhancement in light utilization efficiency.

Meanwhile, the light generated from the light emitting device modules 723 is incident upon the diffusion sheet 740. The optical films 760 are disposed over the diffusion sheet 740. The optical films 760 may include a diffusion film 766, a prism film 750 and a protection film 764.

As apparent from the above description, in the light emitting device package according to each of the above-described embodiments, the heat sink formed to extend from the lead frames extend along a side surface of the body, so that it may be possible to enhance the heat sink function and heat dissipation function of the lead frames. Accordingly, it may be possible to obtain more excellent heat dissipation effects and to achieve an enhancement in reliability.

Although embodiments have been described with reference to a number of illustrative embodiments thereof, it should be understood that numerous other modifications and applications may be devised by those skilled in the art that will fall within the intrinsic aspects of the embodiments. More particularly, various variations and modifications are possible in concrete constituent elements of the embodiments. In addition, it is to be understood that differences relevant to the variations and modifications fall within the spirit and scope of the present disclosure defined in the appended claims.

What is claimed is:

1. A light emitting device package comprising:
a body comprising a cavity, and a recess formed at a bottom surface of the body;
first and second lead frames mounted in the body; and
a light source electrically connected with the first and second lead frames;
wherein at least one of the first and second lead frames has a heat sink which is extended from a portion of the first or the second lead frames, and is disposed in the recess, wherein the body further comprises a first coupler formed on at least a portion of the body, and
wherein the heat sink comprises a second coupler, to which the first coupler is coupled.

2. The light emitting device package according to claim 1, wherein the heat sink is connected at least a portion of one slide surface of the body.

3. The light emitting device package according to claim 1, wherein the heat sink has at least a portion contacting the recess.

4. The light emitting device package according to claim 1, wherein the heat sink has at least one bent portion.

5. The light emitting device package according claim 4, wherein the bent portion is disposed at a corner region of the body.

6. The light emitting device package according to claim 4, wherein the bent portion has a rounded portion.

7. The light emitting device package according to claim 1, wherein:
the heat sink is extended from the first lead frame; and
the light source is mounted on the first lead frame.

8. The light emitting device package according to claim 7, wherein the first lead frame forms an anode terminal.

9. The light emitting device package according to claim 1, wherein the recess has a width greater than a width of the heat sink.

10. The light emitting device package according to claim 1, wherein the recess has a depth greater than a thickness of the heat sink.

11. The light emitting device package according to claim 1, wherein:
the first coupler is a groove; and
the second coupler is a protrusion to be coupled with the groove.

12. The light emitting device package according to claim 1, wherein:
the first coupler is a protrusion; and
the second coupler is a groove to be coupled with the protrusion.

13. The light emitting device package according to claim 1, wherein the heat sink has a hole through at least a portion of the heat sink.

14. The light emitting device package according to claim 13, wherein at least a portion of the body is protruded through the hole.

15. The light emitting device package according to claim 1, wherein the heat sink has at least a portion in which roughness are formed.

16. The light emitting device package according to claim 1, wherein the heat sink is made of an identical material to the first and second lead frames.

17. The light emitting device package according to claim 1, wherein the heat sink comprises at least one of titanium (Ti), copper (Cu), nickel (Ni), gold (Au), chromium (Cr), tantalum (Ta), platinum (Pt), tin (Sn), silver (Ag), phosphor (P), aluminum (Al), indium (In), palladium (Pd), cobalt (Co), silicon (Si), germanium (Ge), hafnium (Hf), ruthenium (Ru), and iron (Fe).

18. The light emitting device package according to claim 1, further comprising:
a bonding layer disposed between at least one side surface of the body and the heat sink.

19. A lighting system comprising a light emitting device package according to claim 1.

20. A backlight unit comprising a light emitting device package according to claim 1.
